(19) United States
(12) Patent Application Publication
(10) Pub. No.: US 2018/0188288 A1
(43) Pub. Date: Jul. 5, 2018

(54) STACKED INSTRUMENT ARCHITECTURE FOR TESTING AND VALIDATION OF ELECTRONIC CIRCUITS

(71) Applicant: Intel Corporation, Santa Clara, CA (US)

(72) Inventors: Erkan Acar, Hillsboro, OR (US); Abram M. Detofsky, Tigard, OR (US); Jin Pan, Portland, OR (US)

(73) Assignee: Intel Corporation, Santa Clara, CA (US)

(21) Appl. No.: 15/393,640

(22) Filed: Dec. 29, 2016

(51) Int. Cl. G01R 1/04; G01R 31/28

(52) U.S. Cl. CPC G01R 1/0466; G01R 31/2834

(57) ABSTRACT

In one embodiment, a device to test one or more electronic components comprises a first card comprising a first test device communicatively coupled to at least a first connector assembly positioned on the first card and a second card comprising a second test device communicatively coupled to at least a second connector assembly positioned on the second card. The at least a first connector assembly is directly communicatively coupled to the at least a second connector assembly to provide a direct communication interface between the first test device and the second test device that is not routed via a backplane. Other embodiments may be described.

### BACKGROUND

The subject matter described herein relates generally to the field of electronic devices and more particularly to a stacked instrument architecture for testing and validation of electronic circuits.

High volume manufacturing testing of electronic components has conventionally been accomplished using automated test equipment (ATE). Many ATEs are architected to use multiple specially designed instrument cards, such as power supply cards, digital signal cards, and timing generators, etc., to meet the test requirements of the devices under the test (DUT). These separate instrument cards are typically interconnected using backplanes or cabling solutions to create modular testers where instruments can be added or removed as needed.

As the demand for power and connectivity increase, backplanes or cabling solutions become increasingly complex and expensive to meet the modularity requirements. In addition, these interconnects become bottlenecks to achieve higher data rates, higher level parallel testing, which limits the test capabilities. Accordingly additional architectures for devices to test one or more electronic components may find utility.

### BRIEF DESCRIPTION OF THE DRAWINGS

The detailed description is described with reference to the accompanying figures.

FIG. 1 is a schematic illustration of an existing architecture for a device to test one or more electronic devices.

FIG. 2 is a schematic illustration of an existing architecture for a device to test one or more electronic devices in accordance with some embodiments.

FIGS. 3-4 illustrate aspects of an existing architecture for a device to test one or more electronic devices in accordance with some embodiments.

FIGS. 5A-5B are schematic illustrations of pin driver circuitry for a device to test one or more electronic devices. in accordance with some embodiments.

FIG. 6 is a schematic illustration of an architecture for a device to test one or more electronic devices in accordance with some embodiments.

FIG. 7 is a flowchart illustrating operations in a method to test one or more electronic devices in accordance with some embodiments.

### DETAILED DESCRIPTION

Described herein are exemplary systems and methods to implement a stacked instrument architecture for testing and validation of electronic circuits. In the following description, numerous specific details are set forth to provide a thorough understanding of various embodiments. However, it will be understood by those skilled in the art that the various embodiments may be practiced without the specific details. In other instances, well-known methods, procedures, components, and circuits have not been illustrated or described in detail so as not to obscure the particular embodiments.

FIG. 1 is a schematic illustration of an existing architecture for an automated test equipment (ATE) device 100 to test one or more electronic devices. Referring to FIG. 1, in some examples ATE device 100 comprises a plurality of instrument cards 120a, 120b, 120c communicatively coupled via a backplane 130 and a connector block 140 to a device under test (DUT) board 160 which comprises one or more DUT sockets 150 to receive one or more electronic components to be tested. The architecture depicted in FIG. 1 has a relatively long electrical path from the DUT socket 250 to the respective instrument cards 120a, 120b, 120c. Electrical signals from the device under test in the DUT socket 150 pass through the DUT board 160, the connector block 140, which typically has a 90 degree rotation, the backplane 130, and the instrument card(s) 120a, 120b, 120c through another connector as illustrated by signal path 170.

All of these elements in the signal path lead to numerous challenges and limitations. For example, the 90-degree orthogonal connectors are typically limited in their signal density. This limits the number of pins that can be installed in a connector, thereby limiting the signal quantity. In addition, manufacturing and assembling instrument cards to the backplanes can be challenging. Furthermore, in order to support modularity, the backplane needs to be designed to accommodate different instrument cards. These limitations complicate the design of the backplane and limit its functionality in certain respects. For example, a slot designed for signal cards may be used for very low current power supply cards. However, this could impact the performance of the power delivery system. In addition, this adds many constraints such as differential and matched signal routing.

In addition to long electrical path and design challenges, traditional ATE devices 100 employ specially designed electrical circuitry, such as pin drivers and parametric measurement units (PMU) in addition to digital pattern analyzers and generators to meet the electrical test requirements of DUT. These custom circuits are typically very expensive and difficult to calibrate, which makes ATE devices 100 costly.

The subject matter described herein addresses these and other issues by providing an improved architecture for automated test equipment (ATE) devices. In various examples described herein an ATE device implements an architecture in which instrument cards comprise electrical connectors positioned in standardized locations to enable an ATE device to be constructed by stacking instrument cards. Similarly, the DUT card(s) comprises electrical connectors positioned in standardized locations to enable the DUT card(s) to be communicatively coupled to the various instrument cards via the electrical connectors. The electrical connectors formed by stacking the cards eliminate the need for a backplane for signal routing. This topology not only reduces the length of the electrical signal path, but also enables a dense signal routing capability.

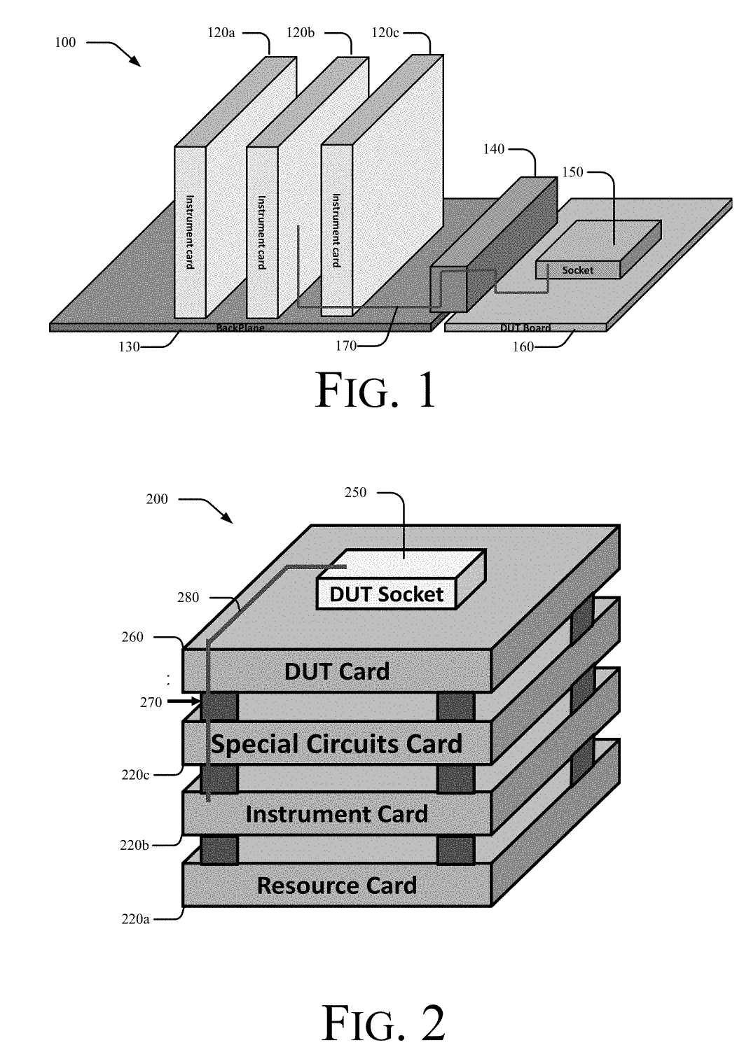

Various aspects of an ATE test device are depicted in FIGS. 2-5. Referring to FIGS. 2-5, in some examples a device 200 to test one or more electronic components comprises a plurality of instrument cards 220a, 220b, 220c comprising a plurality of test devices and at least one device under test (DUT) card 260 comprising a socket 250 to receive the one or more electronic components to be tested. In the example depicted in FIG. 2, the instrument cards comprise a resource card 220a, an instrument card 220b, and a special circuits card 220c. Instrument cards 220a, 220b, 220c may be referred to collectively herein by as instrument cards 220.

In some examples the resource card 220a may comprise one or more resources to be used by the test device 200. For example, resource card 220a may comprise one or more of a power supply, a power converter, a communication interface, or other resources used by the test device 200.

In some examples the instrument card 220b may comprise one or more test instruments to execute testing of an electronic component. Suitable examples of test devices may comprise one or more of analog signal generators, analog signal analyzers, pattern generators, Clock sources, timing recovery circuits, digital processors, power supplies, radio frequency devices, optical interfaces.

In some example the special circuits card 220c may comprise one or more of analog signal generators, analog signal analyzers, pattern generators, clock sources, timing recovery circuits, digital processors, power supplies, radio frequency devices, optical interfaces. It should be noted that that the special circuits card is an optional building block; the device will work without it. The instrument card capabilities can be expanded by adding more special circuits cards.

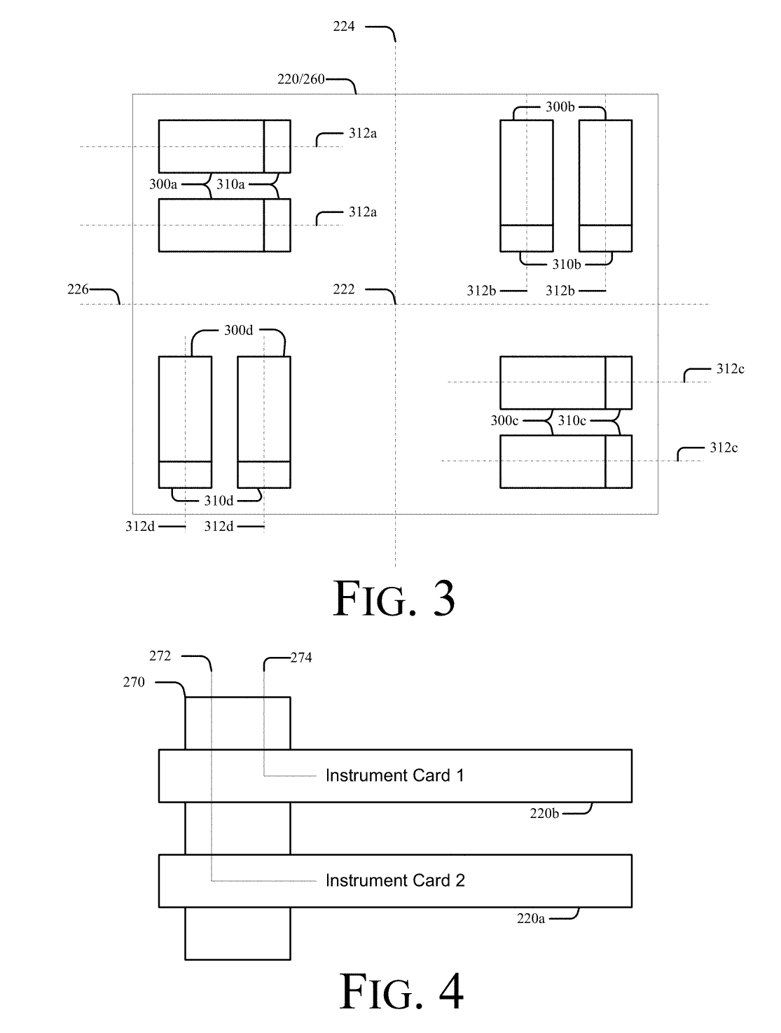

Referring to FIGS. 2-3, in some examples the instrument cards 220 and the at least one DUT card 260 comprise connector assemblies 300a, 300b, 300c, 300d to provide a direct communication interface 270 between plurality of instrument cards 220 and the and the one or more electronic components to be tested on the DUT card 260 such that the signal path 280 is routed via the communication interface 270 directly between connectors such that a backplane is not required. Connector assemblies 300a, 300b, 300c, 300d may be referred to collectively herein by as connector assemblies 300.

In some examples the connector assemblies 300 are arranged in predetermined locations with respect to a central position 222 on the respective instrument card 220 (or DUT card 260) such that the connector assemblies form electrical interconnects when the test cards are stacked. As illustrated in FIG. 3, in some examples the first connector set 300a is positioned in a first corner of the instrument cards 220 (or DUT card 260), the second connector set 300b is positioned in a second corner of the instrument cards 220 (or DUT card 260), the third connector set 300c is positioned in a third corner of the instrument cards 220 (or DUT card 260), and the fourth connector set 300d is positioned in a fourth corner of the instrument cards 220 (or DUT card 260).

In the example depicted in FIG. 3 the connector sets 300 are substantially rectangular in shape and the first connector set 300a and the third connector set 300c are disposed in a first orientation, while the second connector set 300b and the fourth connector set 300d are disposed in a second orientation, approximately perpendicular to the first orientation. More particularly, the connectors in first connector set 310a have a length that is disposed along a longitudinal axis 312a and the connectors in the third connector set 300c have a length that is disposed along a longitudinal axis 312c. The respective longitudinal axes 312a, 312c are disposed in an orientation that is horizontal in FIG. 3. By contrast, the connectors in second connector set 310b have a length that is disposed along a longitudinal axis 312b and the connectors in the fourth connector set 300d have a length that is disposed along a longitudinal axis 312d. The respective longitudinal axes 312b, 312d are disposed in an orientation that is vertical in FIG. 3. Thus, the connectors are positioned such that they exhibit a 90 degree rotational symmetry when rotated about the central position 222 of the instrument card 220 (or DUT card 260). Thus, adjacent cards can be connected in any of four orientations.

In some examples the connector assemblies 300a, 300b, 300c, 300d comprise a plurality of pins 310a, 310b, 310c, 310d which are dedicated to shared system resources, e.g., Clock distribution network, high speed control interfaces, power supplies, trigger network, and/or relay control circuits,

Further, in some examples the connector assemblies 300a, 300b, 300c, 300d comprise at least one pin coupled to a power supply, e.g., on the resource card 220a.

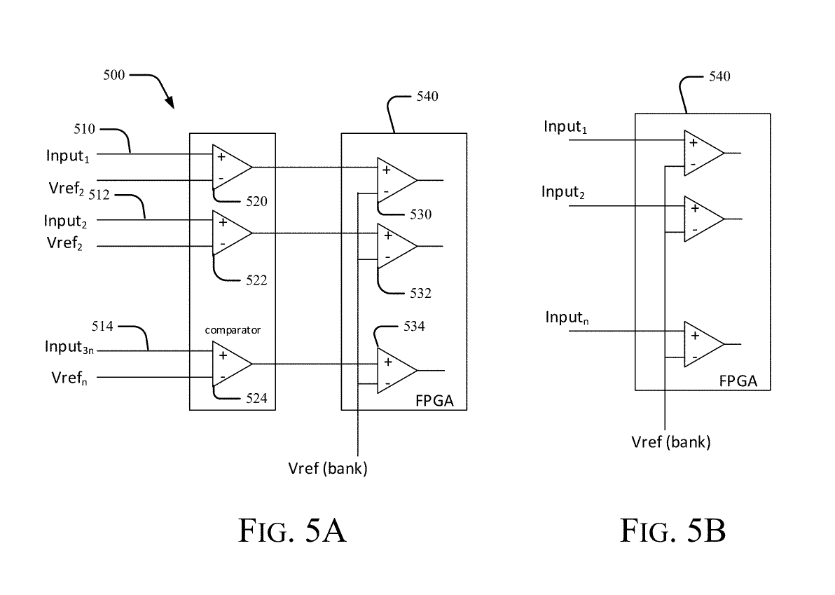

When the cards are stacked, as illustrated in FIG. 2, the connector assemblies 300 form electrical interconnects between the socket 250 on the device under test (DUT) card 250 and the respective instrument cards 220. As illustrated in FIG. 4, the respective instrument cards 220 utilize the communication interface 270 defined by the connectors 300 to access the signals that interface with an electronic component in the socket 250 on the DUT card 260. If an instrument card 220 does not use a particular signal then the signal passes through the connector to a different instrument card, where it may be consumed by another instrument. In the example depicted in FIG. 4, the signal 272 passes through instrument card 1 to be routed to instrument card 220. By contrast, signal 274 is routed to instrument card 1.

FIGS. 5A-5B are schematic illustrations of pin driver circuitry for a device to test one or more electronic devices. in accordance with some embodiments. Referring to FIG. 5A, traditional testers contain dedicated pin driver circuitry 500 to sweep a logic level of the inputs (i.e., Input1 510, Input₂ 512, Inputₙ 514) individually for input signal margining. This circuitry 500 includes comparators 520, 522, 524 for each respective input 510, 512, 514. The internal comparators 530, 532, 534 in the FPGA (field programmable gate array) are not used.

Referring to FIG. 5B, in some examples described herein the dedicated circuitry 500 for input logic level determination may be eliminated. In such examples margining may be accomplished by driving the FPGA Rx reference voltage (Vref) for the bank from a minimum voltage level to a maximum. As the Rx reference voltage is driven higher, signals that have a digital-high value fail to pass the reference voltage. The voltage level of the incoming signal can be determined by counting the number of times a signal fails to pass the reference voltage. This completely eliminates the need for a sophisticated pin driver which requires complex circuitry to achieve the same goal.

Further, timing controls in the FPGA 540 can be employed to control signal timing and meet edge placement requirements. Many FPGAs have timing controls within 20 picoseconds (ps), which is significantly better than any commercially available pin driver solution that is used by the traditional ATE solutions.

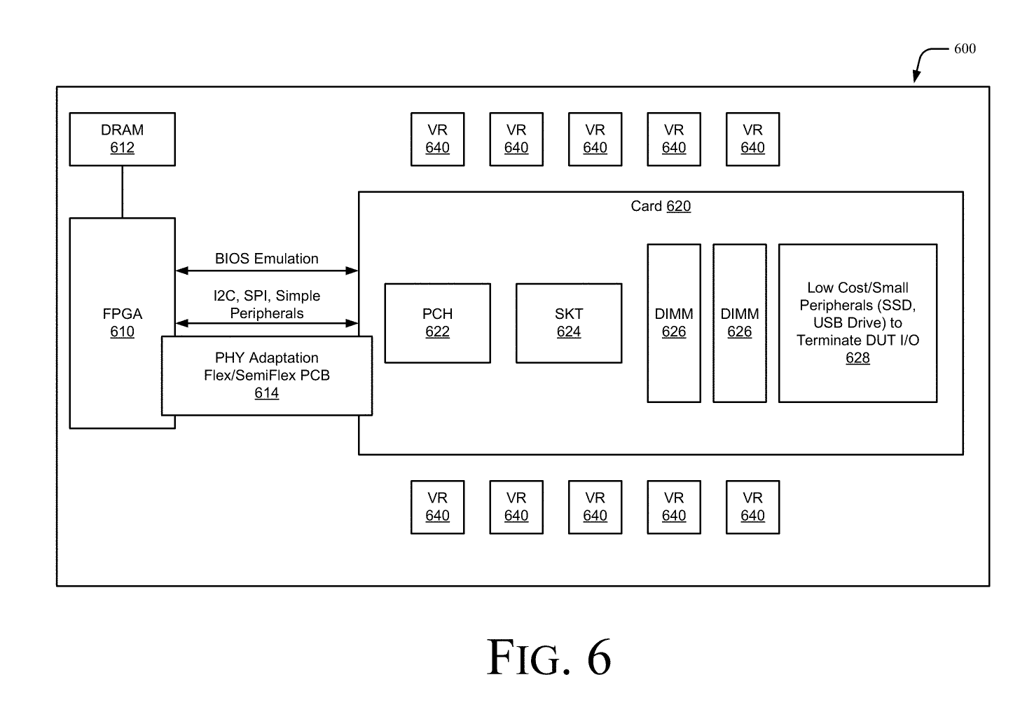

FIG. 6 is a schematic illustration of an example architecture of an instrument card 600, which may correspond to one of the instrument cards 220. In the example depicted in FIG. 6 an instrument card 600 may comprise a controller such as a field programmable gate array 610 coupled to an active memory such as a dynamic random access memory (DRAM) module 610. The FPGA 610 may be coupled to a daughter card 620 which, in turn, may comprise a platform control hub (PCH) 622. Among other things, the PCH 622 provides an interface to input/output (I/O) devices coupled to the card 620. Card 620 may comprise a socket 624 to receive one or more processing devices or other control logic and memory such as one or more direct in-line memory modules (DIMMs) 626. Further, the card 620 may comprise other peripherals 628 coupled to the PCH 622. In various embodiments, integrated drive electronics (IDE) or small computer system interface (SCSI) hard drive(s), universal serial bus (USB) port(s), a keyboard, a mouse, parallel port(s), serial port(s), floppy disk drive(s), digital output support (e.g., digital video interface (DVI)), and the like. The instrument card may further comprise one or more voltage regulators 640.

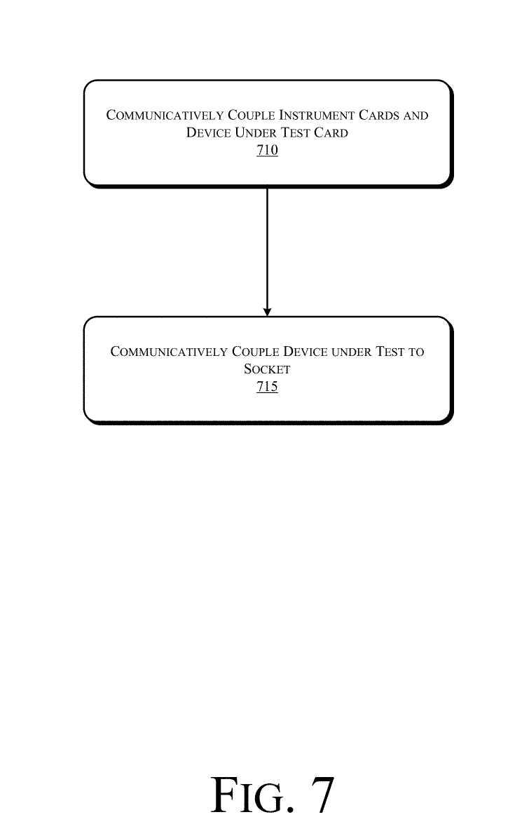

FIG. 7 is a flowchart illustrating operations in a method to test one or more electronic devices in accordance with some embodiments. Referring to FIG. 7, in one example at operation 710 a device under test (DUT) card such as DUT card 260 is communicatively coupled to one or more instrument cards such as the instrument cards 220 depicted in FIG. 2. By way of example, one or more instrument cards 220 may be communicatively coupled to the device under test (DUT) card 260 by stacking the instrument cards 220 and the DUT card 260 such that the connectors 300 are communicatively connected to establish a communication interface 270 between the DUT card 260 and the respective instrument cards 220.

At operation 715 a device under test (e.g., an electronic component) is communicatively coupled to the socket 250 in the DUT card 260. In some examples the electronic component may be positioned in the socket automatically using automated instruments, while in other examples the electronic component may be positioned in the socket manually. Once in place, the test instrument on instrument cards 220 may be activated to implement a test on the electronic component in the socket 250.

Thus, there is described herein an architecture and associated methods to test electronic components. The following pertains to further examples.

Example 1 is a device to test one or more electronic components, comprising a first instrument card comprising a first test device communicatively coupled to at least a first connector assembly positioned on the first card; and a second instrument card comprising a second test device communicatively coupled to at least a second connector assembly positioned on the second card, wherein the at least a first connector assembly is directly communicatively coupled to the at least a second connector assembly to provide a direct communication interface between the first instrument card and the second instrument card that is not routed via a backplane.

Example 2 may optionally include the subject matter of example 1, wherein the first instrument card comprises a first plurality of connector assemblies arranged in predetermined locations with respect to a central position on the first instrument card; and the second instrument card comprises a second plurality of connector assemblies arranged in corresponding predetermined locations with respect to a central position on the second instrument card.

Example 3 may optionally include the subject matter of any one of examples 1-2, wherein the first plurality of connector assemblies comprises a first connector set positioned in a first corner of the first instrument card; a second connector set positioned in a second corner of the first instrument card; a third connector set positioned in a third corner of the first instrument card; and a fourth connector set positioned in a second corner of the first instrument card.

Example 4 may optionally include the subject matter of any one of examples 1-3, wherein the first connector set and the third connector set are disposed in a first orientation; and the second connector set and the fourth connector set are disposed in a second orientation, approximately perpendicular to the first orientation.

Example 5 may optionally include the subject matter of any one of examples 1-4, wherein the second plurality of connector assemblies comprises a first connector set positioned in a first corner of the second instrument card; a second connector set positioned in a second corner of the second instrument card; a third connector set positioned in a third corner of the second instrument card; and a fourth connector set positioned in a fourth corner of the second instrument card.

Example 6 may optionally include the subject matter of any one of examples 1-5, wherein the first connector set and the third connector set are disposed in a first orientation; and the second connector set and the fourth connector set are disposed in a second orientation, approximately perpendicular to the first orientation.

Example 7 may optionally include the subject matter of any one of examples 1-6, further comprising a device under test (DUT) card comprising a socket to receive the one or more electronic components to be tested and communicatively coupled to at least a third connector assembly, wherein the at least a third connector assembly is communicatively coupled to the at least a second connector assembly of the second instrument card to provide a communication interface between the first instrument card, the second instrument card, and the one or more electronic components to be tested on the device under test (DUT) card.

Example 8 may optionally include the subject matter of any one of examples 1-7, wherein the device under test (DUT) card comprises a third plurality of connector assemblies arranged in predetermined locations with respect to a central position on the device under test (DUT) card.

Example 9 may optionally include the subject matter of any one of examples 1-8, wherein the third plurality of connector assemblies comprises a first connector set positioned in a first corner of the device under test (DUT) card; a second connector set positioned in a second corner of the device under test (DUT) card; a third connector set positioned in a third corner of the device under test (DUT) card; and a fourth connector set positioned in a fourth corner of the device under test (DUT) card

Example 10 may optionally include the subject matter of any one of examples 1-9, wherein the first connector set and the third connector set are disposed in a first orientation; and the second connector set and the fourth connector set are disposed in a second orientation, approximately perpendicular to the first orientation

Example 11 is a device to test one or more electronic components, comprising a plurality of instrument cards comprising a plurality of test devices; and at least one device under test (DUT) card comprising a socket to receive the one or more electronic components to be tested, wherein the plurality of instrument cards and the at least one DUT card comprise connector assemblies to provide a direct communication interface between plurality of test cards and the one or more electronic components to be tested that is not routed via a backplane

Example 12 may optionally include the subject matter of any one of example 11, wherein the connector assemblies are arranged in predetermined locations with respect to a central position on the respective instrument cards such that the connector assemblies form electrical interconnects when the test cards are stacked.

Example 13 may optionally include the subject matter of any one of examples 11-12, wherein the connector assemblies form a communication bus between the device under test (DUT) card and the plurality of instrument cards.

Example 14 may optionally include the subject matter of any one of examples 11-13, wherein the connector assemblies comprise a plurality of pins dedicated to shared system resources.

Example 15 may optionally include the subject matter of any one of examples 11-14, wherein the connector assemblies comprise at least one pin coupled to a power supply.

Example 16 is a method to test one or more electronic components, comprising communicatively coupling a plurality of instrument cards comprising a plurality of test devices; and communicatively coupling the plurality of instrument cards to at least one device under test (DUT) card comprising a socket to receive the one or more electronic components to be tested, wherein the plurality of instrument and the at least one DUT card comprise connector assemblies to provide a direct communication interface between plurality of instrument cards and the one or more electronic components to be tested that is not routed via a backplane.

Example 17 may optionally include the subject matter of example 15, wherein the connector assemblies are arranged in predetermined locations with respect to a central position on the respective instrument cards such that the connector assemblies form electrical interconnects when the test cards are stacked.

Example 18 may optionally include the subject matter of any one of examples 15-17, wherein, wherein the connector assemblies for a communication bus between the device under test (DUT) card and the plurality of instrument cards.

Example 19 may optionally include the subject matter of any one of examples 15-18, wherein the connector assemblies comprise a plurality of pins dedicated to shared system resources.

Example 20 may optionally include the subject matter of any one of examples 15-19, wherein the connector assemblies comprise at least one pin coupled to a power supply.

The terms “logic instructions” as referred to herein relates to expressions which may be understood by one or more machines for performing one or more logical operations. For example, logic instructions may comprise instructions which are interpretable by a processor compiler for executing one or more operations on one or more data objects. However, this is merely an example of machine-readable instructions and embodiments are not limited in this respect.

The terms “computer readable medium” as referred to herein relates to media capable of maintaining expressions which are perceivable by one or more machines. For example, a computer readable medium may comprise one or more storage devices for storing computer readable instructions or data. Such storage devices may comprise storage media such as, for example, optical, magnetic or semiconductor storage media. However, this is merely an example of a computer readable medium and embodiments are not limited in this respect.

The term “logic” as referred to herein relates to structure for performing one or more logical operations. For example, logic may comprise circuitry which provides one or more output signals based upon one or more input signals. Such circuitry may comprise a finite state machine which receives a digital input and provides a digital output, or circuitry which provides one or more analog output signals in response to one or more analog input signals. Such circuitry may be provided in an application specific integrated circuit (ASIC) or field programmable gate array (FPGA). Also, logic may comprise machine-readable instructions stored in a memory in combination with processing circuitry to execute such machine-readable instructions. However, these are merely examples of structures which may provide logic and embodiments are not limited in this respect.

Some of the methods described herein may be embodied as logic instructions on a computer-readable medium. When executed on a processor, the logic instructions cause a processor to be programmed as a special-purpose machine that implements the described methods. The processor, when configured by the logic instructions to execute the methods described herein, constitutes structure for performing the described methods. Alternatively, the methods described herein may be reduced to logic on, e.g., a field programmable gate array (FPGA), an application specific integrated circuit (ASIC) or the like.

In the description and claims, the terms coupled and connected, along with their derivatives, may be used. In particular embodiments, connected may be used to indicate that two or more elements are in direct physical or electrical contact with each other. Coupled may mean that two or more elements are in direct physical or electrical contact. However, coupled may also mean that two or more elements may not be in direct contact with each other, but yet may still cooperate or interact with each other.

Reference in the specification to “one embodiment” or “some embodiments” means that a particular feature, structure, or characteristic described in connection with the embodiment is included in at least an implementation. The appearances of the phrase “in one embodiment” in various places in the specification may or may not be all referring to the same embodiment.

Although embodiments have been described in language specific to structural features and/or methodological acts, it is to be understood that claimed subject matter may not be limited to the specific features or acts described. Rather, the specific features and acts are disclosed as sample forms of implementing the claimed subject matter.

What is claimed is:

1. A device to test one or more electronic components, comprising:
a first instrument card comprising a first test device communicatively coupled to at least a first connector assembly positioned on the first card; and
a second instrument card comprising a second test device communicatively coupled to at least a second connector assembly positioned on the second card,
wherein the at least a first connector assembly is directly communicatively coupled to the at least a second connector assembly to provide a direct communication interface between the first instrument card and the second instrument card that is not routed via a backplane.

2. The device of claim 1, wherein:
the first instrument card comprises a first plurality of connector assemblies arranged in predetermined locations with respect to a central position on the first instrument card; and
the second instrument card comprises a second plurality of connector assemblies arranged in corresponding predetermined locations with respect to a central position on the second instrument card.

3. The device of claim 2, wherein the first plurality of connector assemblies comprises:
a first connector set positioned in a first corner of the first instrument card;
a second connector set positioned in a second corner of the first instrument card;
a third connector set positioned in a third corner of the first instrument card; and
a fourth connector set positioned in a second corner of the first instrument card.

4. The device of claim 3, wherein:
the first connector set and the third connector set are disposed in a first orientation; and
the second connector set and the fourth connector set are disposed in a second orientation, approximately perpendicular to the first orientation.

5. The device of claim 4, wherein the second plurality of connector assemblies comprises:
a first connector set positioned in a first corner of the second instrument card;
a second connector set positioned in a second corner of the second instrument card;
a third connector set positioned in a third corner of the second instrument card; and
a fourth connector set positioned in a fourth corner of the second instrument card.

6. The device of claim 5, wherein:
the first connector set and the third connector set are disposed in a first orientation; and
the second connector set and the fourth connector set are disposed in a second orientation, approximately perpendicular to the first orientation.

7. The device of claim 1, further comprising:
a device under test (DUT) card comprising a socket to receive the one or more electronic components to be tested and communicatively coupled to at least a third connector assembly,
wherein the at least a third connector assembly is communicatively coupled to the at least a second connector assembly of the second instrument card to provide a communication interface between the first instrument card, the second instrument card, and the one or more electronic components to be tested on the device under test (DUT) card.

8. The device of claim 7, wherein:
the device under test (DUT) card comprises a third plurality of connector assemblies arranged in predetermined locations with respect to a central position on the device under test (DUT) card.

9. The device of claim 8, wherein the third plurality of connector assemblies comprises:
a first connector set positioned in a first corner of the device under test (DUT) card;
a second connector set positioned in a second corner of the device under test (DUT) card;
a third connector set positioned in a third corner of the device under test (DUT) card; and
a fourth connector set positioned in a fourth corner of the device under test (DUT) card.

10. The device of claim 9, wherein:
the first connector set and the third connector set are disposed in a first orientation; and
the second connector set and the fourth connector set are disposed in a second orientation, approximately perpendicular to the first orientation.

11. A device to test one or more electronic components, comprising:
a plurality of instrument cards comprising a plurality of test devices; and
at least one device under test (DUT) card comprising a socket to receive the one or more electronic components to be tested,
wherein the plurality of instrument cards and the at least one DUT card comprise connector assemblies to provide a direct communication interface between plurality of test cards and the one or more electronic components to be tested that is not routed via a backplane.

12. The device of claim 11, wherein the connector assemblies are arranged in predetermined locations with respect to a central position on the respective instrument cards such that the connector assemblies form electrical interconnects when the test cards are stacked.

13. The device of claim 11, wherein the connector assemblies form a communication bus between the device under test (DUT) card and the plurality of instrument cards.

14. The device of claim 11, wherein the connector assemblies comprise a plurality of pins dedicated to shared system resources.

15. The device of claim 14, wherein the connector assemblies comprise at least one pin coupled to a power supply.

16. A method to test one or more electronic components, comprising:
communicatively coupling a plurality of instrument cards comprising a plurality of test devices; and
communicatively coupling the plurality of instrument cards to at least one device under test (DUT) card comprising a socket to receive the one or more electronic components to be tested,
wherein the plurality of instrument and the at least one DUT card comprise connector assemblies to provide a direct communication interface between plurality of instrument cards and the one or more electronic components to be tested that is not routed via a backplane.

17. The method of claim 16, wherein the connector assemblies are arranged in predetermined locations with respect to a central position on the respective instrument cards such that the connector assemblies form electrical interconnects when the test cards are stacked.

18. The method of claim 16, wherein the connector assemblies for a communication bus between the device under test (DUT) card and the plurality of instrument cards.

19. The method of claim 16, wherein the connector assemblies comprise a plurality of pins dedicated to shared system resources.

20. The method of claim 16, wherein the connector assemblies comprise at least one pin coupled to a power supply.
